(19) United States
(12) Patent Application Publication
(10) Pub. No.: US 2025/0371807 A1
(43) Pub. Date: Dec. 4, 2025

(54) HOST, TRACKING SYSTEM, AND TRACKING METHOD

(71) Applicant: HTC Corporation, Taoyuan City (TW)

(72) Inventor: Ping-Chang Hsieh, Taoyuan City (TW)

(73) Assignee: HTC Corporation, Taoyuan City (TW)

(21) Appl. No.: 19/002,617

(22) Filed: Dec. 26, 2024

Related U.S. Application Data
(60) Provisional application No. 63/655,089, filed on Jun. 3, 2024.

(51) Int. Cl. G06T 19/00; G01R 33/07; G06T 13/40

(52) U.S. Cl. CPC G06T 19/00; G01R 33/07; G06T 13/40

(57) ABSTRACT

A host, a tracking system, and a tracking method are described herein. The host includes a storage circuit and a processor. The storage circuit is configured to store a program code. The processor is coupled to the storage circuit and is configured to access the program code to execute: obtaining an object magnetic variation from a magnetometer, wherein the magnetometer and an object magnet are disposed on a real object in a real world; determining a real object behavior of the real object based on the object magnetic variation; and controlling a virtual object in a virtual world based on the real object behavior.

### CROSS-REFERENCE TO RELATED APPLICATION

This application claims the priority benefit of U.S. provisional application Ser. No. 63/655,089, filed on Jun. 3, 2024. The entirety of the above-mentioned patent application is hereby incorporated by reference herein and made a part of this specification.

### BACKGROUND

### Technical Field

The disclosure relates to a host; particularly, the disclosure relates to a host, a tracking system, and a tracking method.

### Description of Related Art

In order to bring an immersive experience to user, technologies related to extended reality (XR), such as augmented reality (AR), virtual reality (VR), and mixed reality (MR) are constantly being developed. AR technology allows a user to bring virtual elements to the real world. VR technology allows a user to enter a whole new virtual world to experience a different life. MR technology merges the real world and the virtual world. Further, to bring a fully immersive experience to the user, visual content, audio content, or contents of other senses may be provided through one or more devices.

### SUMMARY

The disclosure is direct to a host, a tracking system, and a tracking method, so as to an efficient and convenient way to tracking various events of a target object in the XR application.

The embodiments of the disclosure provide a host. The host includes a storage circuit and a processor. The storage circuit is configured to store a program code. The processor is coupled to the storage circuit and is configured to access the program code to execute: obtaining an object magnetic variation from a magnetometer, wherein the magnetometer and an object magnet are disposed on a real object in a real world; determining a real object behavior of the real object based on the object magnetic variation; and controlling a virtual object in a virtual world based on the real object behavior.

The embodiments of the disclosure provide a tracking system. The tracking system includes an object magnet, a magnetometer, a storage circuit and a processor. The object magnet is disposed on a real object in a real world. The magnetometer is disposed on the real object and configured to obtain an object magnetic variation of the real object. The storage circuit is configured to store a program code. The processor is coupled to the storage circuit and is configured to access the program code to execute: obtaining the object magnetic variation from the magnetometer; determining a real object behavior of the real object based on the object magnetic variation; and controlling a virtual object in a virtual world based on the real object behavior.

The embodiments of the disclosure provide a tracking method. The tracking method includes: obtaining, through a magnetometer, an object magnetic variation, wherein the magnetometer and an object magnet are disposed on a real object in a real world; determining, through a processor, a real object behavior of the real object based on the object magnetic variation; and controlling, through the processor, a virtual object in a virtual world based on the real object behavior.

Based on the above, according to the host, the tracking system, and the tracking method, various events of a target object may be distinguished by utilizing only one magnetic sensor, thereby decreasing the design complexity, the cost, and the weight of the target object.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1A is a schematic diagram of a host according to an embodiment of the disclosure.

FIG. 1B is a schematic diagram of a tracking system according to an embodiment of the disclosure.

FIG. 2A is a schematic diagram of a tracking scenario according to an embodiment of the disclosure.

FIG. 2B is a schematic diagram of a tracking scenario according to an embodiment of the disclosure.

FIG. 3A is a schematic diagram of a tracking scenario according to an embodiment of the disclosure.

FIG. 3B is a schematic diagram of a tracking scenario according to an embodiment of the disclosure.

FIG. 3C is a schematic diagram of a tracking scenario according to an embodiment of the disclosure.

FIG. 4 is a schematic flowchart of a tracking method according to an embodiment of the disclosure.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

An XR application may involve integrating a tracking system, which is equipped with emitters and/or sensors, into a target device or a target object. For example, in order to need to detect various events of a gun (e.g., a slider movement, a slider lock, a trigger pull, a magazine reload, and a safety switch pull), the gun must be equipped with a sophisticated tracking system. That is, the tracking system may require multiple sensors, such as switches, mechanic sensors, and optical sensors, to detect different actions and states of the gun. However, the proliferation of sensors, while enhancing tracking capabilities, may introduce challenges related to design complexity, increased cost, and added weight to the target device or the target object. Therefore, it is the pursuit of people skilled in the art to provide an efficient and convenient way to tracking various events of a target object in the XR application.

To solve this problem, this disclosure presents a tracking system that utilizes a single sensor to accurately detect various events, thereby reducing system complexity and cost. Specifically, a magnetic sensor and a magnet may be disposed on a target object and the magnetic sensor is configured to detect magnetic value variation of the target object while various events occur. In this manner, various events of a target object may be distinguished by utilizing only one magnetic sensor, thereby decreasing the design complexity, the cost, and the weight of the target object.

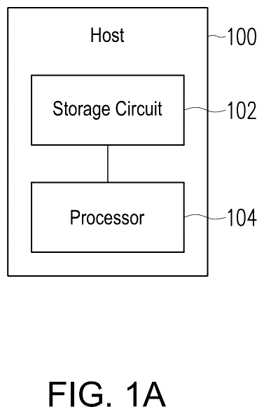

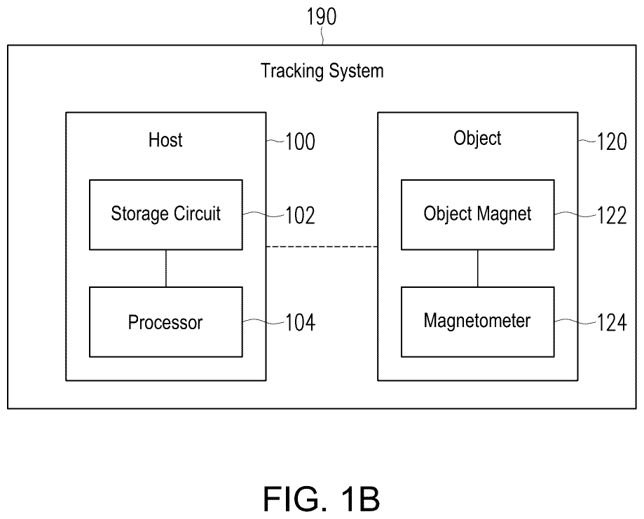

FIG. 1A is a schematic diagram of a host according to an embodiment of the disclosure. In various embodiments, a host 100 may be any smart device and/or computer device. In some embodiments, the host 100 may be any electronic device capable of providing reality services (e.g., AR/VR/MR services, or the like). In some embodiments, the host 100 may be implemented as an XR device, such as a pair of AR/VR glasses and/or a head-mounted display (HMD) device. In some embodiments, the host 100 may be a computer and/or a server, and the host 100 may provide the computed results (e.g., AR/VR/MR contents) to other external display device(s) (e.g., the HMD), such that the external display device(s) can show the computed results to the user. However, this disclosure is not limited thereto.

In FIG. 1A, the host 100 includes a storage circuit 102 and a processor 104. The storage circuit 102 is one or a combination of a stationary or mobile random access memory (RAM), read-only memory (ROM), flash memory, hard disk, or any other similar device, and which records a plurality of modules and/or a program code that can be executed by the processor 104.

The processor 104 may be coupled with the storage circuit 102, and the processor 104 may be, for example, a general purpose processor, a special purpose processor, a conventional processor, a digital signal processor (DSP), a plurality of microprocessors, one or more microprocessors in association with a DSP core, a controller, a microcontroller, Application Specific Integrated Circuits (ASIC), Field Programmable Gate Array (FPGA) circuits, any other type of integrated circuit (IC), a state machine, and the like.

In the embodiments of the disclosure, the processor 104 may access the modules and/or the program code stored in the storage circuit 102 to implement the tracking method provided in the disclosure, which would be further discussed in the following.

FIG. 1B is a schematic diagram of a tracking system according to an embodiment of the disclosure. In FIG. 1B, a tracking system 190 may include the host 100, an object magnet 122 and a magnetometer 124. The object magnet 122 and the magnetometer 124 may be disposed on an object 120. The details of the host 100 may refer to FIG. 1A, while the details are not redundantly described seriatim herein.

In some embodiments, the host 100 may include or communicate with a magnetic sensor. The magnetic sensor may be the magnetometer 124 and the magnetometer may be a fluxgate magnetometer, a Hall effect magnetometer, an overhauser magnetometer, or an atomic magnetometer, other similar devices, or a combination of these devices. In some embodiments, the magnetic sensor may be disposed on an object to be tracked (e.g., the object 120). However, this disclosure is not limited thereto.

In some embodiments, the host 100 and the object 120 may further include a communication circuit and the communication circuit may include, for example, a wired network module, a wireless network module, a Bluetooth module, an infrared module, a radio frequency identification (RFID) module, a Zigbee network module, or a near field communication (NFC) network module, but the disclosure is not limited thereto. That is, the host 100 and the object 120 may communicate with each other through either wired communication or wireless communication.

In the embodiments of the disclosure, the tracking system 190 may utilize the host 100, the object magnet 122, and the magnetometer 124 to implement the tracking method provided in the disclosure, which would be further discussed in the following.

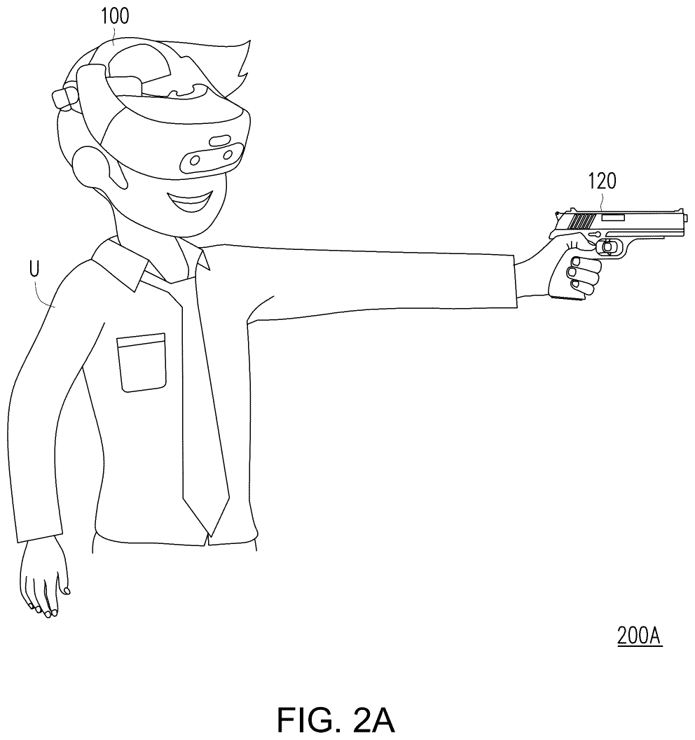

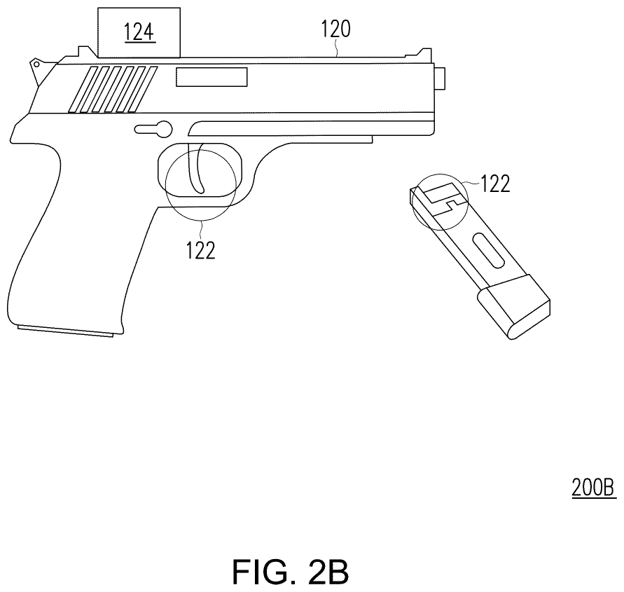

FIG. 2A is a schematic diagram of a tracking scenario according to an embodiment of the disclosure. FIG. 2B is a schematic diagram of a tracking scenario according to an embodiment of the disclosure. In FIG. 2A, a tracking scenario 200A depicts that how a user U interacts with the host 100 and the object 120 within an XR environment. In FIG. 2B, a tracking scenario 200B depicts detailed components of the object 120 and how the components function within the tracking system 190.

Reference is made to FIG. 2A first. In the tracking scenario 200A, in a real world, the user U may wear the host 100 on the head and hold a real object (i.e., the object 120) in the hand. Simultaneously, the user U may feel immersed in a virtual world as a virtual character, holding a virtual object with a virtual hand. Moreover, by manipulating the object 120 in the real world, corresponding changes may be reflected in the virtual object in the virtual world (e.g., an event may be triggered in the virtual world). That is, an XR experience may seamlessly blend the real world and the virtual world, allowing the user U to interact with the virtual object through physical manipulations on the object 120.

For example, the object 120 may be a gun and the user U may perform various operations on the gun to cause various behaviors of the gun (also known as the real object behaviors), such as moving a slider of the gun, locking the slider, pulling a trigger of the gun, reloading a magazine of the gun, or pulling a safety switch of the gun. In addition, the object 120 may include the object magnet 122 and the magnetometer 124. Furthermore, the processor 104 may be configured to obtain an object magnetic variation through the magnetometer 124 and determine a real object behavior of the object 120 based on the object magnetic variation. Then, based on the real object behavior of the object 120 in the real world, the processor 104 may be configured to control the virtual object in the virtual world. In this manner, corresponding changes may be reflected in the virtual object by only utilizing one signal sensor, thereby decreasing the design complexity, the cost, and the weight of the target object. The process of the determination of the real object behavior of the object 120 would be further discussed in the following.

Reference is now made to FIG. 2B. In the tracking scenario 200B, the object 120 may include the object magnet 122 and the magnetometer 124. It is noted that, a number of the magnet 122 may be more than one. For example, in FIG. 2B, a first magnet is disposed on the trigger of the object 120 and a second magnet is disposed on the top of the magazine. However, this disclosure is not limited thereto.

It is worth mentioned that, the object 120 may include a plurality of components. For example, when the object 120 is the gun, the gun may include a main body, a slider, a trigger, a magazine, and a safety switch. By interacting with different components of the gun, different behaviors of the gun may be performed. It is noted that, due to a metal structure of each component or the object magnet 124 attached to each component, while a certain behavior is performed, a certain magnetic variation may be generated. This certain magnetic variation may be called as an event magnetic pattern. That is to say, by comparing an object magnetic variation detected by the magnetometer 124 with the event magnetic pattern, whether a behavior of the object 120 is performed may be determined. In other words, the processor 104 may be configured to determine whether the object magnetic variation match an event magnetic pattern or not. Further, in response to the object magnetic variation matching the event magnetic pattern, the processor 104 may be configured to generate an event trigger signal. Furthermore, the processor 104 may be configured to control the virtual object based on the event trigger signal. However, this disclosure is not limited thereto.

In one embodiment, a number of the behavior of the object 120 may be more than one. That is, there may be a plurality of behaviors of the object 120 in the real world. Correspondingly, there may be a plurality of events that may be triggered in the virtual world. In other words, the processor 104 may be configured to determine whether the object magnetic variation match one of a plurality of event magnetic patterns or not. Further, in response to the object magnetic variation matching the one of the plurality of event magnetic patterns, the processor 104 may be configured to generate one of a plurality of event trigger signals. Furthermore, the processor 104 may be configured to control the virtual object based on the one of the plurality of event trigger signals.

In one embodiment, when one event is trigger, an event animation related to the virtual object may be played in the virtual world. That is, in response to the real object behavior being determined, the processor 104 may be configured to play an event animation related to the virtual object in the virtual world. However, this disclosure is not limited thereto.

It is noted that, the Earth's magnetic field influences every location on the planet. That is to say, if an object magnetic variation caused by a behavior of the object 120 is smaller than an Earth's magnetic field at a location of the object 120, the object magnetic variation may go undetected or may be mistaken as a noise. Therefore, in order to make sure the object magnetic variation is detectable by the magnetometer 124, the object magnet 122 may be disposed on the object 120 to enhance the object magnetic variation. Alternatively, instead of disposed an additional magnet on the object 120 as the object magnet 122, each component of the object 120 may be designed to form a specific metal structure (e.g., a plurality of active/passive coils), creating the object magnet 122. That is, the object magnet 122 may be an additional component attached to the object 120 or a built-in metal structure of the object 120. Furthermore, the object magnetic 122 may be configured to enhance the object magnetic variation so that a minimal value of the object magnetic variation is stronger than an Earth's magnetic field at a location of the object 120. However, this disclosure is not limited thereto.

In addition, in order to enhance the object magnetic variation caused by a behavior of the object 120, a magnetic field provided by the object magnet 122 and/or a location of the object magnet 122 disposing on the object 120 may be taken into concern. That is, the object magnet 122 may be configured to provide an object magnetic field to the magnetometer 124 and the object magnetic field is stronger than an Earth's magnetic field provided to the magnetometer at a location of the object 120.

To be more specific, the Earth's magnetic field strength varies with latitude, ranging approximately from 25 to 65 microtesla (μT). For an eCompass system, a magnetic field variation generated by a magnet (e.g., the object magnet 122) typically needs to be 3 to 5 times of the ambient magnetic field strength, which is generally appropriate. The required magnetic field variation also depends on fluctuations in the ambient magnetic field. Further, a distance between an eCompass (e.g., the magnetometer 124) and the magnet as well as the strength of the magnet are critical factors to be considered. The closer the magnet to the eCompass, the stronger the resulting magnetic field is, allowing for the use of a weaker magnet. Conversely, if the magnet is farther from the eCompass, a stronger magnet will be required to achieve the same effect.

That is, an object magnetic field of the object magnetic 122 may be greater than 75-195 microtesla (μT) (e.g., 3 times of the Earth's magnetic field). Further, the object magnet 122 may be disposed as close to magnetometer 124 as possible to achieve a best enhancement effect of the object magnetic variation. For example, as shown in FIG. 2B, assuming that the magnetometer is disposed on a back position of slider, the object magnet 122 may be disposed on a trigger of the gun or on a top of the magazine of the gun. However, this disclosure is not limited thereto.

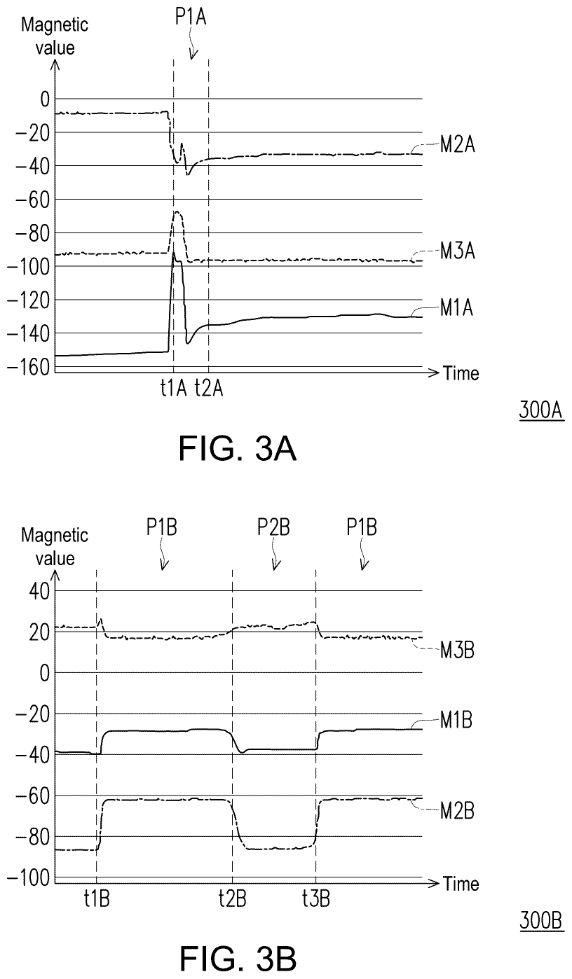

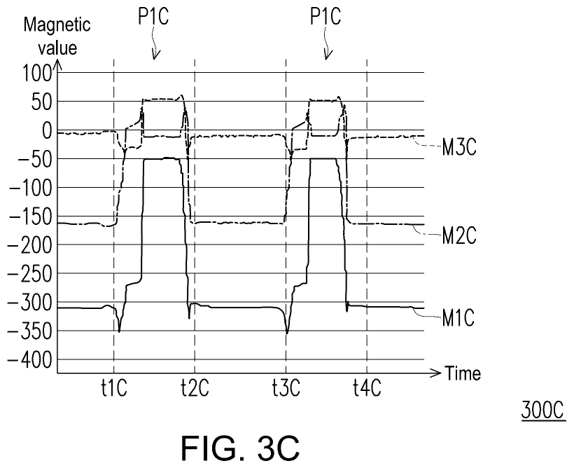

FIG. 3A is a schematic diagram of a tracking scenario according to an embodiment of the disclosure. FIG. 3B is a schematic diagram of a tracking scenario according to an embodiment of the disclosure. FIG. 3C is a schematic diagram of a tracking scenario according to an embodiment of the disclosure. FIG. 3A to FIG. 3C depict some event magnetic pattern caused by different behavior of the object 120. The horizontal axis indicates the time and the vertical axis indicates the magnetic field value (unit: microtesla (μT)). In FIG. 3A, a tracking scenario 300A depicts a magnetic pattern that when a trigger of a gun is pulled. In FIG. 3B, a tracking scenario 300B depicts two magnetic patterns that when a magazine of the gun is removed and reloaded. In FIG. 3C, a tracking scenario 300C depicts a magnetic pattern that when a slider of the gun is locked.

Reference is made to FIG. 3A first. A magnetic field value may include three channels (e.g., for three directions x, y, z). That is, the magnetic field value may include a first magnetic field value MIA in a first direction, a second magnetic field value M2A in a second direction, and a third magnetic field value M3A in a third direction. By detecting the magnetic field value of the object 120 over time through the magnetometer 124, an object magnetic variation may be obtained. It is noted that, during a first period P1A between a time t1A to a time t2A, when the trigger of the gun is pulled, a specific pattern of the object magnetic variation may be observed. This specific pattern may be called as the event magnetic pattern. That is, the event magnetic pattern may be pre-stored in the storage circuit 102 and may be utilized to be compared with an object magnetic variation obtained by the magnetometer 124 in the future. In this manner, various events of a target object may be distinguished by utilizing only one magnetic sensor, thereby decreasing the design complexity, the cost, and the weight of the target object.

Moreover, since the trigger of the gun is pulled in the first direction, the change of the magnetic field value in the first direction (i.e., M1A) may be greater than the change of the magnetic field value in the second direction (i.e., M2A) or the third direction (i.e., M3A). That is, instead of monitoring the magnetic field value in all three directions, the magnetic field value in the direction related to the behavior of the object 120 may be utilized to determine the behavior of the object 120. In other words, the object magnetic variation may include values in three directions and the processor 104 may be configured to determine the real object behavior of the real object based on a value in a direction related to the real object behavior. However, this disclosure is not limited thereto.

Reference is now made to FIG. 3B and FIG. 3C. The tracking scenario 300B depicts two magnetic patterns that when a magazine of the gun is removed and reloaded and the tracking scenario 300C depicts a magnetic pattern that when a slider of the gun is locked. The details of the magnetic field value may refer to the description of FIG. 3A, while the details are not redundantly described seriatim herein.

Similar as FIG. 3A, in FIG. 3B and FIG. 3C, the magnetic field values may include first magnetic field values M1B, M1C in the first direction, second magnetic field values M2B, M2C in the second direction, and third magnetic field values M3B, M3C in the third direction. In FIG. 3B, during a first period P1B between a time t1B to a time t2B or during the first period P1B after a time t3B, when the magazine of the gun is removed, a specific pattern of the object magnetic variation may be observed. Further, during a second period P2B between the time t2B to the time t3B, when the magazine of the gun is reloaded, a specific pattern of the object magnetic variation may be observed. Furthermore, in FIG. 3C, during a first period P1C between a time t1C to a time t2C or during the first period P1C between a time t3C and a time t4C, when the slider of the gun is locked, a specific pattern of the object magnetic variation may be observed. These specific patterns may be also called as the event magnetic patterns.

It is noted that, while the preceding examples have centered on the gun, the methodology presented may be adaptable to a wide range of object interactions, including actions like drawing a bow, manipulating a vehicle (e.g., steering, accelerating, activating windshield wipers, signaling turns, shifting gears), or other object interactions. In addition, the methodology may be also adaptable to an identification of controllers and the identification of controllers may involve assigning roles and tracking devices installed on different controllers. The magnetic field variations on the controller may provide information about the corresponding ID and type of each controller. However, this disclosure is not limited thereto.

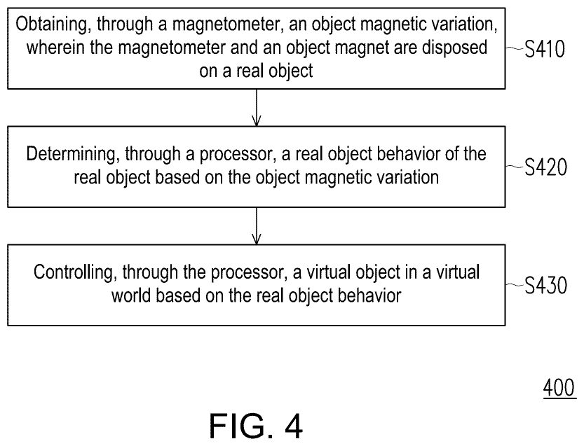

FIG. 4 is a schematic flowchart of a tracking method according to an embodiment of the disclosure. In FIG. 4, a tracking method 400 includes a step S410, a step S420, and a step S430.

In the step S410, an object magnetic variation is obtained through the magnetometer 124 and the magnetometer 124 and the object magnet 122 may be disposed on a real object in a real world. In the step S420, a real object behavior of the real object may be determined through the processor 104 based on the object magnetic variation. In the step S430, a virtual object in a virtual world may be controlled through the processor 104 based on the real object behavior.

In addition, the implementation details of the tracking method 400 may be referred to the descriptions of FIG. 1 to FIG. 3C to obtain sufficient teachings, suggestions, and implementation embodiments, while the details are not redundantly described seriatim herein.

In summary, according to the host 100, the tracking system 190, and the tracking method 400, various events of a target object may be distinguished by utilizing only one magnetic sensor, thereby decreasing the design complexity, the cost, and the weight of the target object.

It will be apparent to those skilled in the art that various modifications and variations can be made to the structure of the present invention without departing from the scope or spirit of the disclosure. In view of the foregoing, it is intended that the present disclosure cover modifications and variations of this invention provided they fall within the scope of the following claims and their equivalents.

What is claimed is:

1. A host, comprising:
a storage circuit, configured to store a program code; and
a processor, coupled to the storage circuit and configured to access the program code to execute:
obtaining an object magnetic variation from a magnetometer, wherein the magnetometer and an object magnet are disposed on a real object in a real world;
determining a real object behavior of the real object based on the object magnetic variation; and
controlling a virtual object in a virtual world based on the real object behavior.

2. The host according to claim 1, wherein the processor is further configured to access the program code to execute:
determining whether the object magnetic variation match an event magnetic pattern or not;
in response to the object magnetic variation matching the event magnetic pattern, generating one of a plurality of event trigger signals; and
controlling the virtual object based on the one of the plurality of event trigger signals.

3. The host according to claim 1, wherein the processor is further configured to access the program code to execute:
determining whether the object magnetic variation match one of a plurality of event magnetic patterns or not;
in response to the object magnetic variation matching the one of the plurality of event magnetic patterns, generating an event trigger signal; and
controlling the virtual object based on the event trigger signal.

4. The host according to claim 1, wherein the processor is further configured to access the program code to execute:
in response to the real object behavior being determined, playing an event animation related to the virtual object in the virtual world.

5. The host according to claim 1, wherein the object magnet is an additional component attached to the object or a built-in metal structure of the object.

6. The host according to claim 1, wherein the object magnetic is configured to enhance the object magnetic variation so that a minimal value of the object magnetic variation is stronger than an Earth's magnetic field at a location of the object.

7. The host according to claim 1, wherein an object magnetic field of the object magnetic is greater than 75-195 microtesla.

8. The host according to claim 1, wherein the real object is a gun and the object magnet is disposed on a trigger of the gun or a top of a magazine of the gun.

9. The host according to claim 1, wherein the real object behavior comprises moving a slider of a gun, locking the slider, pulling a trigger of the gun, reloading a magazine of the gun, or pulling a safety switch of the gun.

10. The host according to claim 1, wherein
the object magnetic variation comprises values in three directions, and the processor is further configured to access the program code to execute:
determining the real object behavior of the real object based on a value in a direction related to the real object behavior.

11. A tracking system, comprising:
an object magnet, disposed on a real object in a real world;
a magnetometer, disposed on the real object and configured to obtain an object magnetic variation of the real object;
a storage circuit, configured to store a program code; and
a processor, coupled to the storage circuit and configured to access the program code to execute:
obtaining the object magnetic variation from the magnetometer;
determining a real object behavior of the real object based on the object magnetic variation; and
controlling a virtual object in a virtual world based on the real object behavior.

12. The tracking system according to claim 11, wherein the processor is further configured to access the program code to execute:
determining whether the object magnetic variation match an event magnetic pattern or not;
in response to the object magnetic variation matching the event magnetic pattern, generating one of a plurality of event trigger signals; and
controlling the virtual object based on the one of the plurality of event trigger signals.

13. The tracking system according to claim 11, wherein the processor is further configured to access the program code to execute:
determining whether the object magnetic variation match one of a plurality of event magnetic patterns or not;
in response to the object magnetic variation matching the one of the plurality of event magnetic patterns, generating an event trigger signal; and
controlling the virtual object based on the event trigger signal.

14. The tracking system according to claim 11, wherein the processor is further configured to access the program code to execute:
in response to the real object behavior being determined, playing an event animation related to the virtual object in the virtual world.

15. The tracking system according to claim 11, wherein the object magnet is an additional component attached to the object or a built-in metal structure of the object.

16. The tracking system according to claim 11, wherein the object magnetic is configured to enhance the object magnetic variation so that a minimal value of the object magnetic variation is stronger than an Earth's magnetic field at a location of the object.

17. The tracking system according to claim 11, wherein an object magnetic field of the object magnetic is greater than 75-195 microtesla.

18. The tracking system according to claim 11, wherein the real object is a gun and the object magnet is disposed on a trigger of the gun or a top of a magazine of the gun.

19. The tracking system according to claim 11, wherein the real object behavior comprises moving a slider of a gun, locking the slider, pulling a trigger of the gun, reloading a magazine of the gun, or pulling a safety switch of the gun.

20. A tracking method, comprising:
obtaining, through a magnetometer, an object magnetic variation, wherein the magnetometer and an object magnet are disposed on a real object in a real world;
determining, through a processor, a real object behavior of the real object based on the object magnetic variation; and
controlling, through the processor, a virtual object in a virtual world based on the real object behavior.
